(19) United States
(12) Patent Application Publication
(10) Pub. No.: US 2020/0194583 A1
(43) Pub. Date: Jun. 18, 2020

(54) METAL SOURCE LDMOS SEMICONDUCTOR DEVICE AND MANUFACTURING METHOD THEREOF

(71) Applicants: ZHENG ZUO, LOS ANGELES, CA (US); NA REN, LOS ANGELES, CA (US); RUIGANG LI, LOS ANGELES, CA (US)

(72) Inventors: ZHENG ZUO, LOS ANGELES, CA (US); NA REN, LOS ANGELES, CA (US); RUIGANG LI, LOS ANGELES, CA (US)

(73) Assignee: AZ Power, Inc, CULVER CITY, CA (US)

(21) Appl. No.: 16/279,735

(22) Filed: Feb. 19, 2019

Related U.S. Application Data
(60) Provisional application No. 62/779,713, filed on Dec. 14, 2018.

(51) Int. Cl. H01L 29/78; H01L 29/08; H01L 29/417; H01L 29/45; H01L 29/66; H01L 21/768; H01L 29/47

(52) U.S. Cl. CPC H01L 29/782; H01L 29/0865; H01L 29/41766; H01L 29/47; H01L 29/66696; H01L 21/76805; H01L 29/7816; H01L 29/456

(57) ABSTRACT

A manufacturing method for a LDMOS semiconductor device may include steps of forming a P-type layer on a P-type substrate; forming a P-type body region and an N-type well under the P-type layer; forming a field oxide on the P-type layer; forming a gate oxide on the P-type body region and field oxide; forming a gate polysilicon on top of the gate oxide; depositing a gate metal silicide on top of the gate polysilicon; depositing a thin film on top of the field oxide, P-type body region and gate silicide; forming a dielectric layer on top of the thin film; forming a first trench in the dielectric layer; forming a second trench underneath the first trench; depositing a metal layer on top of the dielectric layer and filling into the first and second trenches; and removing the metal on top of the dielectric layer.

### CROSS-REFERENCE TO RELATED APPLICATIONS

This application claims priority under 35 U.S.C. § 119 (e) to U.S. Provisional Patent Application Ser. No. 62/779,713, filed on Dec. 14, 2018, the entire contents of which are hereby incorporated by reference.

### FIELD OF THE INVENTION

The present invention relates to semiconductor field, especially a Lateral Double-Diffused Metal-Oxide-Semiconductor (LDMOS) device with metal source and manufacturing method thereof.

### BACKGROUND OF THE INVENTION

Lateral double-diffused metal-oxide-semiconductor (LDMOS) is a high voltage transistor based on lateral double-diffused metal-oxide semiconductor structure. The channel doping concentration can be optimized by the lateral diffusion from source hole to the area underneath the gate channel, and the device blocking voltage can be improved. LDMOS device can be divided into N-type and P-type. N-type discrete LDMOS device used in microwave radio frequency field (also called RFLDMOS) is widely applied in wireless communication and radar signal transmission. The gate length, channel lateral diffusion, extended drain design, source series resistance, gate series resistance, and field plate structure have crucial impacts on the device RF performance, power performance and reliability. In order to reduce the source series resistance, the following techniques are commonly used.

The first technique is to connect double face diffusion-based source to reduce source series resistance. At source position, use high concentration diffusion or ion implantation to introduce doping materials from substrate direction, then apply high temperature diffusion process to connect the upper and lower source dopants together. The source series resistance can be reduced, and lateral diffusion region can be shrunk to reduce the chip size.

The second technique is to connect multiple implantation and diffusion-based source to reduce source series resistance. At source position, use high concentration diffusion or ion implantation to introduce doping materials from substrate direction. Form epitaxial layer with certain thickness on active layer and use high concentration diffusion or ion implantation to introduce doping materials, then apply high temperature diffusion process to connect the upper and lower source dopants together. The source series resistance can be reduced.

The third technique is to connect polysilicon-based source to reduce source series resistance. Before general process, use plasma etching to etch through epitaxial layer and deposit doped polysilicon by LPCVD method to fill the source hole. Due to a lower resistivity of doped polysilicon than doped silicon, the source series resistance can be reduced.

The fourth technique is to connect Tungsten-based source to reduce source series resistance. Before general process, use plasma etching to etch through epitaxial layer and deposit tungsten to fill the source hole. Due to a lower resistivity of tungsten than doped silicon, the source series resistance can be reduced.

However, the techniques listed above are all based on doping material source and PN junction-based channel structure, and the source series resistance is still high, so the device performance is limited. Also, the manufacturing process in the above techniques is complicated which may increase the fabrication costs. Therefore, there remains a need for a new and improved fabrication technique to overcome the problems stated above while reducing the source series resistance.

### SUMMARY OF THE INVENTION

It is an object of the present invention to provide a Lateral Double-Diffused Metal-Oxide-Semiconductor (LDMOS) semiconductor device with a metal source used to form a Schottky junction or an Ohmic contact instead of conventional PN junction-based source structure.

It is another object of the present invention to provide an LDMOS semiconductor device having the metal source electrode with high conductivity to provide high carrier concentration to the gate channel, so the device source series resistance can be effectively reduced.

It is a further object of the present invention to provide an LDMOS semiconductor device with improved gain, driving current and high frequency performance.

In one aspect, a manufacturing method for a metal source LDMOS semiconductor device may include steps of forming a P-type layer on a P-type substrate; forming a P-type body region and an N-type well under an upper surface of the P-type layer; forming a field oxide on the upper surface of the P-type layer; forming a gate oxide on a portion of an upper surface of the P-type body region and on a portion of the field oxide; forming a gate polysilicon on top of the gate oxide; and depositing a gate metal silicide on top of the gate polysilicon.

In one embodiment, the substrate is a heavily-doped P-type substrate, and the P-type layer is either a well formed by diffusion/implantation process or epitaxially grown on top of the substrate. In another embodiment, the P-type body region can be formed by a diffusion process and separated from the N-type well with a predetermined distance. In a further embodiment, the gate metal silicide is formed by metal deposition on top of the gate polysilicon with high temperature annealing.

The manufacturing method for a metal source LDMOS semiconductor device may further includes step of depositing a SiON thin film on top of the field oxide, the P-type body region and the gate silicide; forming an SiO₂ dielectric layer on top of the SiON thin film; forming a first trench on the SiO₂ dielectric layer with a photoresist as a mask layer; forming a second trench (underneath the first trench) in the P-type body region penetrating through the P-type layer and extending to the P-type substrate; depositing a metal layer on top of the SiO₂ dielectric layer and filling into the second trench to form a Schottky junction or an Ohmic contact with the P-type body region; and removing the metal on top of the SiO₂ dielectric layer.

In one embodiment, the SiO₂ dielectric layer can be formed by a Chemical Vapor Deposition (CVD) process, and the photoresist can be removed with a strong oxidizer at 100° C. In another embodiment, the second trench is formed by plasma dry etching with SiO₂ dielectric layer as the mask layer with a controlled etching rate. In a further embodiment, the metal layer is deposited on the SiO₂ dielectric layer by sputtering or evaporation.

It is noted that the metal for the metal layer includes, but not limited to, Tb, Er, or Yb, which has a work function >0.6 eV high than the fermi level of P-type silicon, and the metal can form a Schottky junction with the P-type body region. In a further embodiment, the metal can use any material as long as the metal can form an Ohmic contact with the P-type body region after high temperature annealing.

The step of removing the metal on top of the SiO₂ dielectric layer involves a chemical and mechanical polishing process, and the metal filled in the trench is remained as a metal source electrode. In the present invention, the metal source is used to form a Schottky junction or an Ohmic contact between the metal electrode and P-type body region. Comparing with conventional PN junction-based source structure, the metal source in the present invention with high conductivity provides high carrier concentration to the gate channel, so the device source series resistance can be effectively reduced.

### BRIEF DESCRIPTION OF THE DRAWINGS

FIG. 1 is a cross-sectional structural view of a metal source LDMOS device in the present invention.

FIGS. 2A to 2G illustrate a manufacturing process of the metal source LDMOS semiconductor device in the present invention.

FIG. 3 illustrates a method of manufacturing the metal source LDMOS device in the present invention.

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

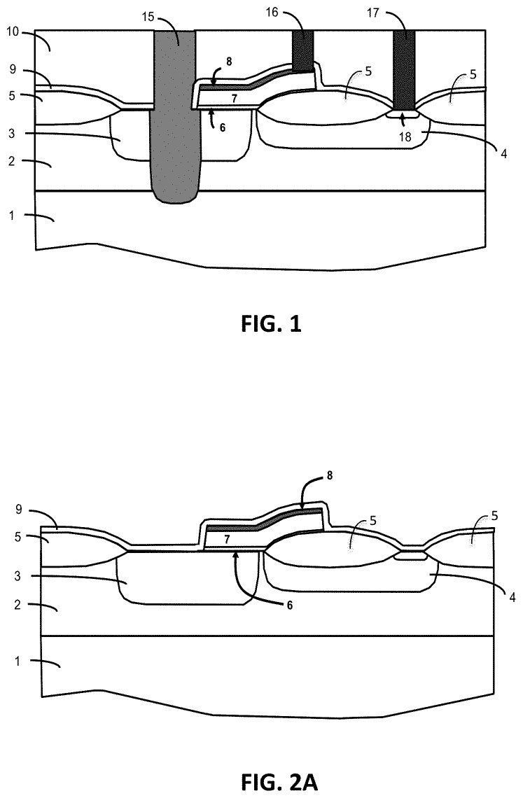

In one aspect, as shown in FIG. 1, a Lateral Double-Diffused Metal-Oxide Semiconductor (LDMOS) device may include a P-type substrate 1, a P-type layer 2, a P-type body region 3, an N-type well 4, an N⁺-type drain region 18, a field oxide 5, a gate oxide 6, a gate polysilicon 7, a gate metal silicide 8, a SiON thin film 9, a SiO₂ dielectric layer 10, a metal source 15, a gate electrode 16, and a drain electrode 17.

In one embodiment, the substrate 1 is heavily P-type doped, and the P-type layer 2 is either a well formed by diffusion/implantation process or epitaxially grown on top of the substrate 1. It is noted that the P-type layer 2 has an upper surface.

Furthermore, the P-type body region 3 is formed by a diffusion process under the upper surface of P-type layer 2, and the N-type well 4 is also formed under the upper surface of P-type layer 2 but separated from the P-type body region 3. It is noted that the N⁺-type drain region 18 is formed under the upper surface of the N-type well 4.

A filed oxide is a thin (on a macroscopic scale) film made up of an oxide of a material which overlies a device substrate to reduce parasitic capacitive coupling between conductors overlying the oxide and the substrate or devices below the oxide layer. In the present invention, the field oxide 5 is grown on a portion of the upper surface of the P-type layer 2, and has an open window on the surface of the P-type body region 3 and N⁺-type drain region 18.

A gate oxide is a dielectric layer that separates the gate terminal of a MOSFET from the underlying source and drain terminals as well as the conductive channel that connects source and drain when the transistor is turned on. The gate oxide 6 in the present invention is grown on a part of the surface of the P-type body region 3, and is partly located on top of the field oxide 5, which is located on the surface of the N-type well 4.

The gate polysilicon 7 is grown on top of the gate oxide 6 and self-aligned with the gate oxide pattern. Polysilicon has become the modern gate material because it is the same chemical composition as the silicon channel beneath the gate oxide. Also, the work-function difference is close to zero, making the threshold voltage lower and ensuring the transistor can be turned on.

A silicide is a compound that has silicon with usually more electropositive elements. In the present invention, the gate metal silicide 8 is formed by metal deposition on top of the gate polysilicon 7 and high temperature annealing. The SiON thin film 9 is grown on top of the field oxide 5, the P-type body region 3 and the gate silicide 8.

The SiO₂ dielectric layer 10 is deposited on top of the SiON thin film 9. In one embodiment, the metal source 15 is formed by trench etching and metal filling process, wherein the trench is formed in the P-type body region 3, penetrated through the P-type layer 2 and extended into the heavily-doped P-type substrate 1. It is noted that the metal source 15 forms a Schottky junction or Ohmic contact with the P-type body region 3.

In one embodiment, the gate electrode 16 is formed by trench etching and metal filling process, wherein the trench is formed in the SiO₂ dielectric layer 10 and SiON thin film 9, and the metal is filled in the trench and in touch with the gate metal silicide 8. Similarly, the drain electrode 17 is formed by trench etching and metal filling process, wherein the trench is formed in the SiO₂ dielectric layer 10 and SiON thin film 9, and the metal is filled in the trench and in touch with the N⁺-type drain region 18.

Comparing with conventional LDMOS devices, the present invention is advantageous because the LDMOS device in the present invention has a metal source formed in the trench of the P-type body region, penetrating through the P well and extending into the P-type substrate, wherein the metal source forms a Schottky junction or Ohmic contact with the P-type body region instead of traditional PN junction in conventional LDMOS devices. The LDMOS device in the present invention uses the metal source electrodes with high conductivity to provide high carrier concentration to the gate channel, so the device source series resistance can be effectively reduced. Therefore, the device's gain, driving current and high frequency performance can be improved.

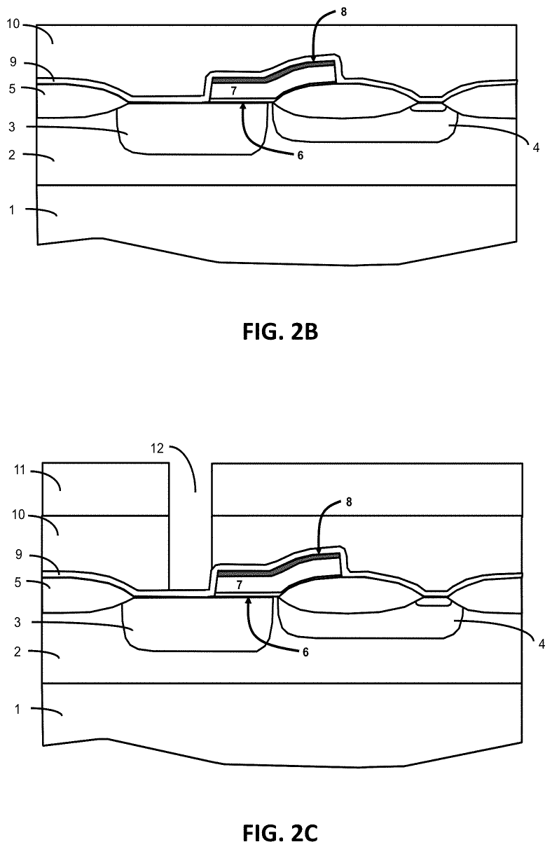

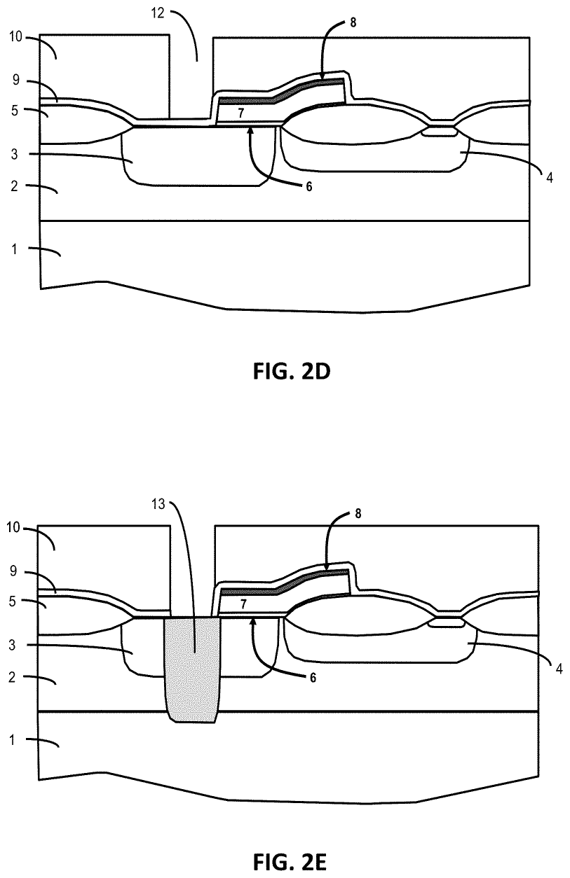

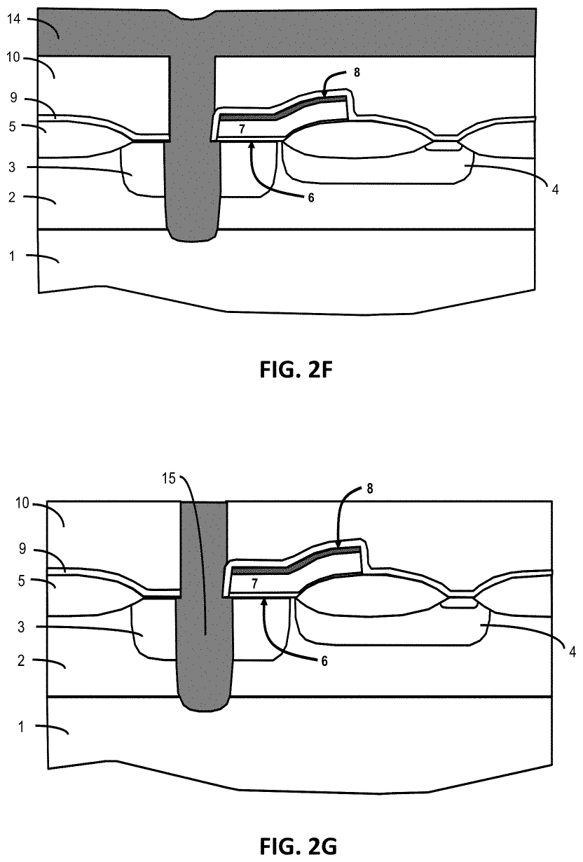

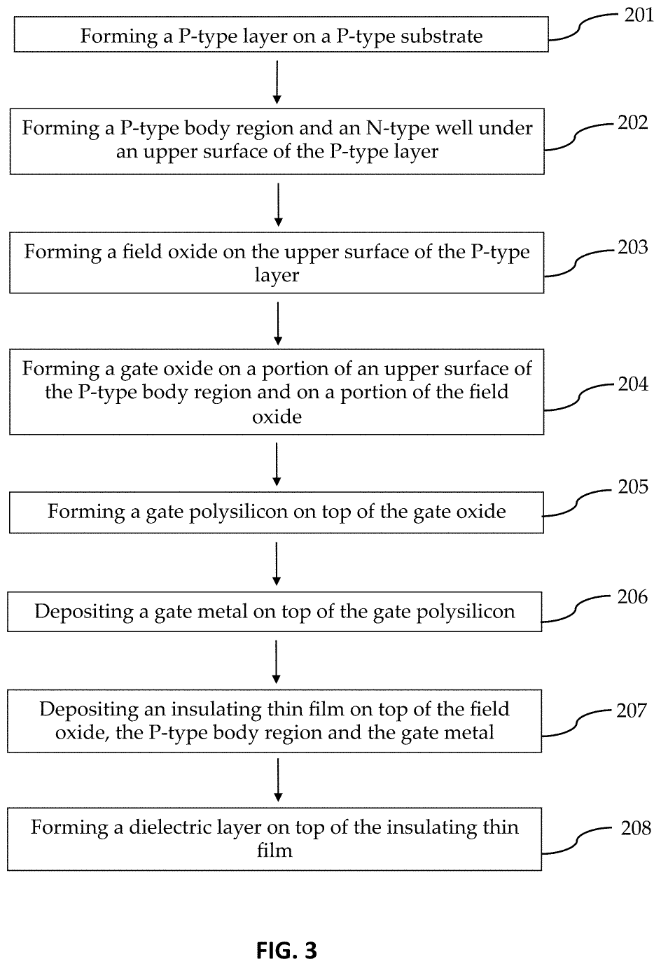

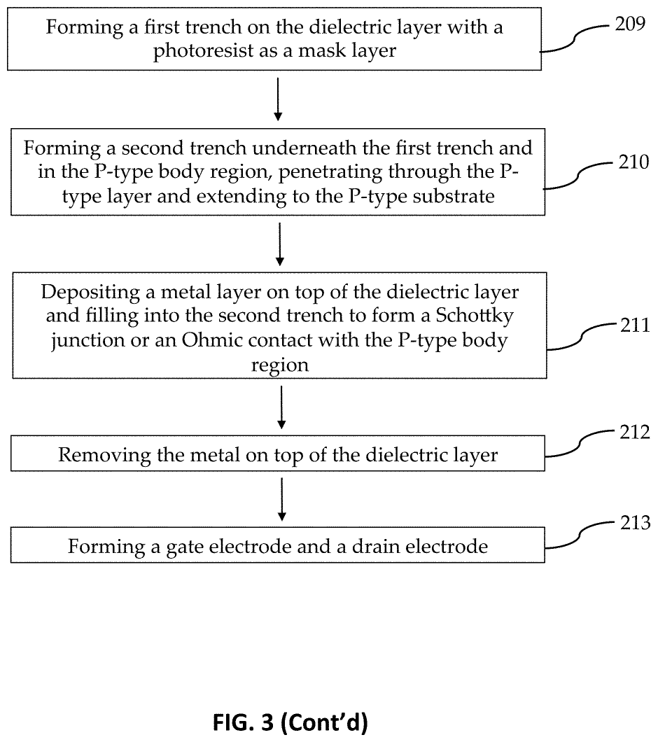

In another aspect, referring to FIGS. 2A-2G, a manufacturing method for a metal source LDMOS semiconductor device may include steps of forming a P-type layer 2 on a P-type substrate 1 (201); forming a P-type body region 3 and an N-type well 4 under an upper surface of the P-type layer 2 (202); forming a field oxide 5 on the upper surface of the P-type layer 2 (203); forming a gate oxide 6 on a portion of an upper surface of the P-type body region 3 and on a portion of the field oxide 5 (204); forming a gate polysilicon 7 on top of the gate oxide 6 (205); and depositing a gate metal 8 on top of the gate polysilicon 7 (206).

In one embodiment, the substrate is a heavily-doped P-type substrate, and the P-type layer 2 is either a well formed by diffusion/implantation process or epitaxially grown on top of the substrate 1. In another embodiment, the P-type body region 3 can be formed by a diffusion process and separated from the N-type well 4 with a predetermined distance. In a further embodiment, the gate metal 8 is silicide and formed by metal deposition on top of the gate polysilicon 7 with high temperature annealing.

The manufacturing method for a metal source LDMOS semiconductor device may further includes steps of depositing an insulating thin film 9 on top of the field oxide 5, the P-type body region 3 and the gate metal 8 (207); forming a dielectric layer 10 on top of the insulating thin film 9 (208); forming a first trench 12 on the dielectric layer 10 with a photoresist 11 as a mask layer (209); forming a second trench 13 (underneath the first trench 12) in the P-type body region 3 penetrating through the P-type layer 2 and extending to the P-type substrate 1 (210); depositing a metal layer 14 on top of the dielectric layer 10 and filling into the second trench 13 to form a Schottky junction or an Ohmic contact with the P-type body region 3 (211); and removing the metal on top of the dielectric layer 10 (212).

In one embodiment, the insulating thin film is SiON thin film; the dielectric layer 10 is SiO₂ and can be formed by a Chemical Vapor Deposition (CVD) process, and the photoresist 11 can be removed with a strong oxidizer at 100° C. In another embodiment, the second trench 13 is formed by plasma dry etching with SiO₂ dielectric layer 10 as the mask layer with a controlled etching rate. In a further embodiment, the metal layer 14 is deposited on the SiO₂ dielectric layer 10 by sputtering or evaporation.

It is noted that the metal for the metal layer 14 includes, but not limited to, Tb, Er, or Yb, which has a work function >0.6 eV high than the fermi level of P-type silicon, and the metal can form a Schottky junction with the P-type body region 3. In a further embodiment, the metal can use any material as long as the metal can form an Ohmic contact with the P-type body region 3 after high temperature annealing.

The step of removing the metal on top of the SiO₂ dielectric layer 10 involves a chemical and mechanical polishing process, and the metal filled in the trench 13 is remained as a metal source electrode 15. In the present invention, the metal source is used to form a Schottky junction or an Ohmic contact between the metal electrode and P-type body region. Comparing with conventional PN junction-based source structure, the metal source 15 in the present invention with high conductivity provides high carrier concentration to the gate channel, so the device source series resistance can be effectively reduced.

The manufacturing method for a metal source LDMOS semiconductor device may further includes a step of forming a gate electrode 16 and a drain electrode 17 (213).

Having described the invention by the description and illustrations above, it should be understood that these are exemplary of the invention and are not to be considered as limiting. Accordingly, the invention is not to be considered as limited by the foregoing description, but includes any equivalent.

What is claimed is:

1. A lateral double-diffused metal-oxide semiconductor (LDMOS) device comprising:
a substrate having a first conductivity type and having a lightly-doped epitaxial layer thereon having an upper surface;
a body region of the first conductive type formed in the epitaxial layer proximate the upper surface;
a well region of a second conductivity type formed in the epitaxial layer proximate the upper surface and spaced from the body region;
a field oxide formed in the epitaxial layer proximate the upper surface;
a gate oxide formed on a portion of an upper surface of the body region and on top of the field oxide which is located on top of the well region;
a gate polysilicon formed on top of the gate oxide;
a gate metal formed on top of the gate polysilicon;
an insulating layer formed on top of the filed oxide, the body region and the gate metal silicide; and
a metal source formed by filling metal in a first trench formed in a dielectric layer formed on top of the insulating layer and a second trench formed in the body region penetrating through the epitaxial layer and extending into the substrate.

2. The LDMOS device of claim 1, wherein the substrate is heavily P-type doped.

3. The LDMOS device of claim 1, further comprising a drain region of the second conductive type formed under an upper surface of the well region.

4. The LDMOS device of claim 1, wherein the dielectric layer is formed by a Chemical Vapor Deposition (CVD) process.

5. The LDMOS device of claim 1, wherein the metal source is made of, but not limited to, Tb, Er, or Yb, which has a work function >0.6 eV high than the fermi level of P-type silicon.

6. The LDMOS device of claim 1, wherein the gate metal is silicide.

7. The LDMOS device of claim 1, wherein the insulating layer is made of a SiON thin film, and the dielectric layer is a SiO₂ layer.

8. The LDMOS device of claim 1, further comprising a gate electrode and a drain electrode.

9. The LDMOS device of claim 1, wherein a Schottky junction is formed between the metal source and the P-type body region.

10. A manufacturing method for a lateral double-diffused metal-oxide semiconductor (LDMOS) device comprising steps of:
forming an epitaxial layer of first conductivity type on a substrate of the first conductivity type;
forming a body region and a well region under an upper surface of the epitaxial layer;
forming a field oxide on the upper surface of the epitaxial layer;
forming a gate oxide on a portion of an upper surface of the body region and on a portion of the field oxide;
forming a gate polysilicon on top of the gate oxide and depositing a gate metal on top of the gate polysilicon;
depositing an insulating layer on top of the field oxide, the body region and the gate metal;
forming a dielectric layer on top of the insulating layer;
forming a first trench on the dielectric layer and a second trench underneath the first trench and in the P-type body region, penetrating through the epitaxial layer and extending to the substrate;
depositing a metal layer on top of the dielectric layer and filling into the first and second trenches to form a metal source as a Schottky junction or an Ohmic contact with the body region; and
removing the metal on top of the dielectric layer.

11. The manufacturing method for a lateral double-diffused metal-oxide semiconductor (LDMOS) device of claim 1, wherein the substrate is a heavily-doped P-type substrate.

12. The manufacturing method for a lateral double-diffused metal-oxide semiconductor (LDMOS) device of claim 1, wherein the body region 3 is formed by a diffusion process and separated from the well region with a predetermined distance.

13. The manufacturing method for a lateral double-diffused metal-oxide semiconductor (LDMOS) device of claim 1, wherein the dielectric layer is formed by a Chemical Vapor Deposition (CVD) process.

14. The manufacturing method for a lateral double-diffused metal-oxide semiconductor (LDMOS) device of claim 1, wherein the metal source is made of, but not limited to, Tb, Er, or Yb, which has a work function >0.6 eV high than the fermi level of P-type silicon.

15. The manufacturing method for a lateral double-diffused metal-oxide semiconductor (LDMOS) device of claim 1, wherein the insulating layer is made of a SiON thin film, and the dielectric layer is a SiO₂ layer.

16. The manufacturing method for a lateral double-diffused metal-oxide semiconductor (LDMOS) device of claim 1, further comprising a step of forming a gate electrode and a drain electrode.
